(19) United States
(12) Patent Application Publication
(10) Pub. No.: US 2022/0081219 A1
(43) Pub. Date: Mar. 17, 2022

(54) Article Transport Facility

(71) Applicant: Daifuku Co., Ltd., Osaka-shi (JP)

(72) Inventor: Hiroshi Otsuka, Hinocho (JP)

(21) Appl. No.: 17/471,742

(22) Filed: Sep. 10, 2021

(30) Foreign Application Priority Data
Sep. 11, 2020 (JP) 2020-153136

(51) Int. Cl. B65G 43/02; B66C 19/00; B66C 13/30; B61B 13/00; H01L 21/677

(52) U.S. Cl. CPC B65G 43/02; B66C 19/00; B66C 13/30; B61B 13/00; B65G 2201/0297; H01L 21/67763; B65G 2203/0283; B65G 2203/0291; H01L 21/67733

(57) ABSTRACT

A control unit causes a lifting unit to perform a lifting operation for raising/lowering a holding unit by executing feedback control for controlling the lifting unit to move a position of the holding unit in a lifting direction closer to a target position while changing the target position, and the control unit executes feedback control with the target position fixed while causing the travel unit to perform a travel operation for traveling along a travel path in a state where the holding unit is holding an article. The control unit reduces a travel operation gain which is a gain of the feedback control during the travel operation to lower than a lifting operation gain which is a gain of the feedback control during the lifting operation.

### CROSS-REFERENCE TO RELATED APPLICATION

This application claims priority to Japanese Patent Application No. 2020-153136 filed Sep. 11, 2020, the disclosure of which is hereby incorporated by reference in its entirety.

### BACKGROUND OF THE INVENTION

### 1. Field of the Invention

The present invention relates to an article transport facility provided with a transport vehicle that travels along a travel path and transport an article, and a control unit that controls operations of the transport vehicle.

### 2. Description of the Related Art

An example of an article transport facility such as the above is disclosed in JP 2017-124885A (Patent Document 1). Hereinafter, reference numerals shown in parentheses in the description of this section are from Patent Document 1. The article transport facility of Patent Document 1 is provided with an article transport device (2) that travels along a travel path and transports an article (3), and a control device (80) that controls operations of the article transport device (2). Patent Document 1 describes a technology for reducing vibration of the article (3) that is caused by travel of a travel unit (11) provided in the article transport device (2). Specifically, Patent Document 1 describes reducing vibration in a vertical direction (Z) of the article (3), by controlling the drive of a lifting motor (21) that raises and lowers a first supporting part (4) that supports the article (3), using a control system such as shown in FIG. 6 of Patent Document 1, during the travel operation of the travel unit (11).

### SUMMARY OF THE INVENTION

Incidentally, the control system shown in FIG. 6 of Patent Document 1 is obtained by a feedback control system for generating basic torque based on position deviation to which is added a vibration suppression torque generation system for generating vibration suppression torque that adds to the basic torque. Thus, the control configuration tends to become complicated, compared with the case where such a vibration suppression torque generation system is unnecessary.

In view of this, it is desired to realize a technology that is able to reduce vibration in the vertical direction that is transmitted to the article during the travel operation of the travel unit with a comparatively simple control configuration.

An article transport facility according to this disclosure is an article transport facility including a transport vehicle configured to travel along a travel path and transport an article, and a control unit configured to control operations of the transport vehicle, the transport vehicle including a travel unit configured to travel along the travel path, a holding unit configured to hold the article, and a lifting unit configured to raise/lower the holding unit in a lifting direction relative to the travel unit, the control unit causing the lifting unit to perform a lifting operation for raising/lowering the holding unit, by executing feedback control for controlling the lifting unit to move a position of the holding unit in the lifting direction closer to a target position while changing the target position, and executing the feedback control with the target position fixed while causing the travel unit to perform a travel operation for traveling along the travel path in a state where the holding unit is holding the article, and the control unit reducing a travel operation gain which is a gain of the feedback control during the travel operation to lower than a lifting operation gain which is a gain of the feedback control during the lifting operation.

In order to shorten the positioning time of a holding unit and the like, it is generally sought to set the gain of feedback control during the lifting operation of the holding unit by the lifting unit (lifting operation gain) comparatively high. According to this configuration, the gain of feedback control during the travel operation of the travel unit (travel operation gain) can be set low, while setting a high lifting operation gain. By setting a low travel operation gain in this way, in the case where the holding unit is displaced from the target position during the travel operation, the amount of corrective force for returning the position of the holding unit in the lifting direction to the target position can be kept at a moderate level, and vibration that is transmitted to the article held by the holding unit can be kept small. In this way, according to this configuration, vibration in the vertical direction that is transmitted to the article during the travel operation of the travel unit can be reduced, with a comparatively simple control configuration that reduces the travel operation gain to lower than the lifting operation gain.

Other features and advantages of the article transport facility will become apparent from the following description of embodiments with reference to the drawings.

### BRIEF DESCRIPTION OF THE DRAWINGS

FIG. 1 is a perspective view of a transport vehicle.

FIG. 2 is a side view of a transport vehicle.

FIG. 3 is a diagram showing an example of a plan layout of a travel path.

FIG. 4 is a plan view showing a transport vehicle that advances along a travel path on the left side at a branch part.

FIG. 5 is a plan view showing a transport vehicle that advances along a travel path on the right side at the branch part.

FIG. 6 is a control block diagram.

FIG. 7 is a block diagram showing a control system of feedback control.

FIG. 8 is a diagram showing an example of temporal change in the pattern of feedback control gain.

### DETAILED DESCRIPTION OF PREFERRED EMBODIMENTS

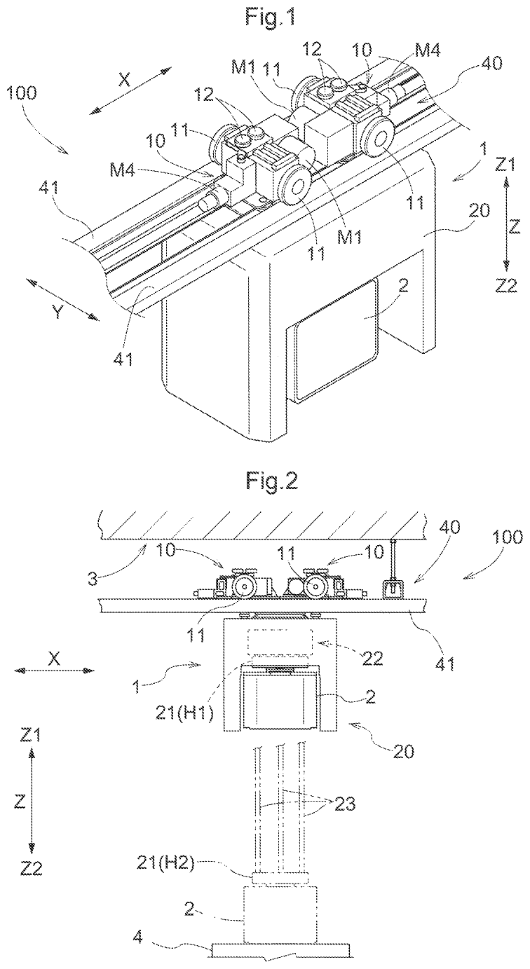

An embodiment of an article transport facility will be described with reference to the drawings. As shown in FIG. 1, an article transport facility 100 is provided with a transport vehicle 1 that travels along a travel path 40 and transports an article 2. Here, the longitudinal direction of the travel path 40 (direction in which the travel path 40 extends) is a path longitudinal direction X, and the width direction of the travel path 40 is a path width direction Y. The path width direction Y is a direction orthogonal to both the path longitudinal direction X and the vertical direction Z.

In the present embodiment, the article transport facility 100 is provided with a travel rail 41 disposed along the travel path 40 (here, a pair of travel rails 41 disposed with an interval therebetween in the path width direction Y), and the transport vehicle 1 travels along the travel rail 41. As shown in FIG. 2, in the present embodiment, the transport vehicle 1 is a ceiling transport vehicle that travels along the travel path 40 formed along a ceiling 3, and the travel rail 41 is supported in a suspended manner from the ceiling 3. Note that the transport vehicle 1 may be a transport vehicle other than a ceiling transport vehicle. A transport vehicle that travels along a travel path formed along the floor can be illustrated as a transport vehicle other than a ceiling transport vehicle. The travel path in this case may be formed with a travel rail, and may also be set in a virtual manner.

As shown in FIGS. 1 and 2, the transport vehicle 1 is provided with a travel unit 10 that travels along the travel path 40. The travel unit 10 travels along the travel rail 41 (here, a pair of travel rails 41). The travel unit 10 is provided with wheels 11 that roll on a travel surface of the travel rails 41, and a travel drive unit M1 (e.g., electric motor such as a servo motor) that rotates the wheels 11. The travel surface of the travel rails 41 is a surface facing an upper side Z1 in the vertical direction Z, and the wheels 11 rotate about an axial center orthogonal to the vertical direction Z. The travel unit 10 travels along the travel rails 41, due to the wheels 11 being rotationally driven by the travel drive unit M1. Although not described in detail, the travel unit 10 is provided with auxiliary wheels that roll on a guide surface of the travel rails 41, and the travel unit 10 travels along the travel rails 41 in a state where the auxiliary wheels are guided in contact with the guide surface of the travel rails 41. The guide surface of the travel rails 41 is a surface facing an inner side in the path width direction Y (side facing the center position between the pair of travel rails 41 in the path width direction Y), and the auxiliary wheels rotate (in this example, freely rotate) about an axial center parallel to the vertical direction Z. In the example shown in FIG. 1, one pair of travel units 10 are provided in the transport vehicle 1 so as to be aligned in the front-back direction of the vehicle body (direction defined with reference to the transport vehicle 1 and parallel to the path longitudinal direction X in a state where the transport vehicle 1 is disposed on the travel path 40).

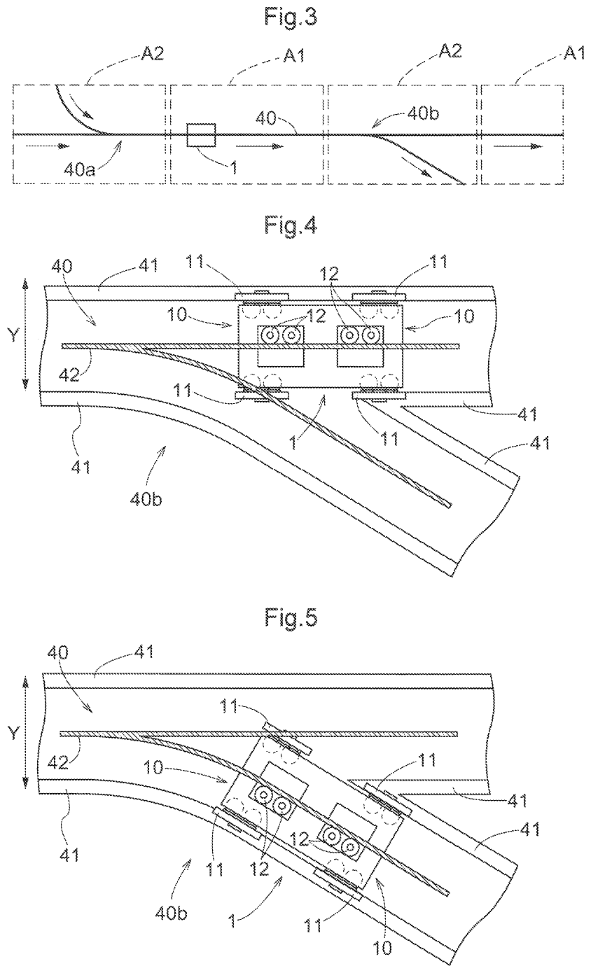

As shown in FIG. 1, in the present embodiment, the travel unit 10 is provided with guide wheels 12 that roll on a guide surface of a guide rail 42 (see FIGS. 4 and 5) that is separate from the travel rails 41. The guide surface of the guide rail 42 is a surface facing one side in the path width direction Y, and the guide wheels 12 rotate (in this example, freely rotate) about an axial center parallel to the vertical direction Z. The guide rail 42 is disposed along the travel path 40, and, here, is disposed in a central part of the travel path 40 in the path width direction Y. The guide rail 42 is provided in parts of the travel path 40 (e.g., merge part 40a, branch part 40b, curved section). As shown in FIG. 3, the merge part 40a is a place where a plurality of travel paths 40 merge into one travel path 40, and the branch part 40b is a place where one travel path 40 branches into a plurality of travel paths 40. In FIG. 3, the travel direction of the transport vehicle 1 is shown with arrows. Also, the curved section is a section formed in a curved shape in plan view (viewed in direction parallel to vertical direction Z) of the travel path 40.

In the present embodiment, the travel unit 10 is provided with a pair of wheels 11 consisting of a wheel 11 that rolls on the travel surface of one of the pair of travel rails 41 and a wheel 11 that rolls on the travel surface of the other of the pair of travel rails 41. In the portions of the travel path 40 where the guide rail 42 is provided, the travel unit 10 can be caused to travel in a posture where only one of the pair of wheels 11 is in contact with the travel rail 41, and the guide wheels 12 are in contact with the guide rail 42 (i.e., in a posture where the load of the travel unit 10 is carried by the travel rail 41 with which the one wheel 11 is in contact and the guide rail 42).

Specifically, as shown in FIG. 4, in the case where the transport vehicle 1 advances along the travel path 40 on the left side (left side when facing in the direction of movement; same applies below) at the branch part 40b, the travel rail 41 on the right side (right side when facing in the direction of movement; same applies below) ends, but the travel unit 10 travels over the part where the travel rail 41 on the right side ends in a posture where the wheel 11 on the left side contacts the travel rail 41 on the left side, and the guide wheels 12 contact the guide rail 42 from the left side. Also, as shown in FIG. 5, in the case where the transport vehicle 1 advances along the travel path 40 on the right side at the branch part 40b, the travel rail 41 on the left side ends, but the travel unit 10 travels over the part where the travel rail 41 on the left side ends in a posture where the wheel 11 on the right side is in contact with the travel rail 41 on the right side, and the guide wheels 12 are in contact with the guide rail 42 from the right side. Although not illustrated, there are also places in the merge part 40a where the travel rail 41 on the right side or left side ends, and the travel unit 10 travels at the merge part 40a in a posture where only one of the pair of wheels 11 is in contact with the travel rails 41, and the guide wheels 12 are in contact with the guide rail 42, similarly to the branch part 40b.

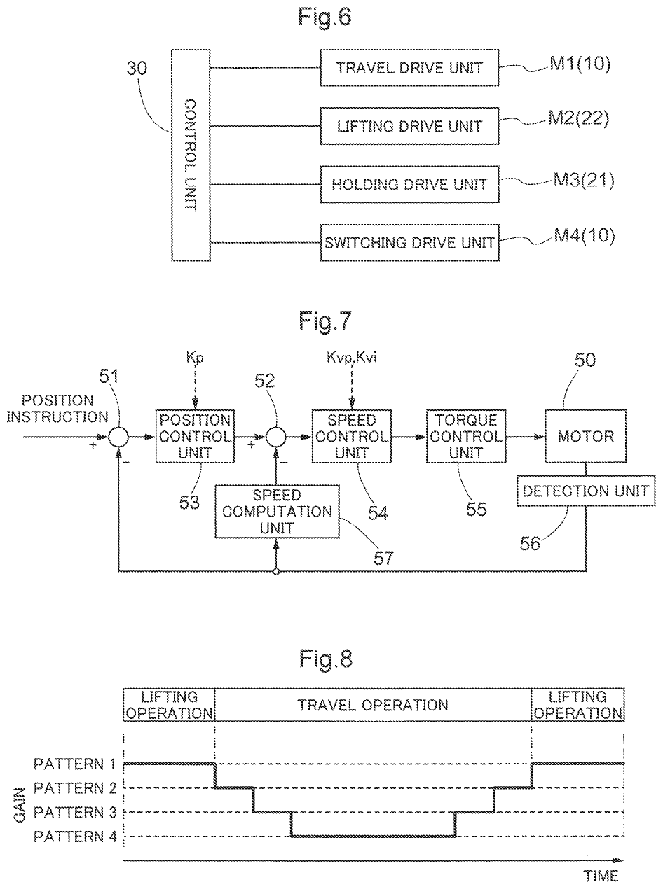

As shown in FIGS. 1 and 6, the travel unit 10 is provided with a switching drive unit M4 (e.g., solenoid or electric motor) that moves the guide wheels 12 in the width direction of the travel unit 10 (direction in which the pair of wheels 11 are arranged side by side), and, due to the drive of the switching drive unit M4, the position of the guide wheels 12 is switched between a right-side guide position (see FIG. 5) in which the guide wheels 12 are disposed on the right side relative to the guide rail 42 and contact the guide rail 42 from the right side, and a left-side guide position (see FIG. 4) in which the guide wheels 12 are on left side relative to the guide rail 42 and contact the guide rail 42 from the left side.

As shown in FIG. 2, the transport vehicle 1 is provided with a holding unit 21 that holds the article 2. In the present embodiment, the holding unit 21 holds the article 2 from the upper side Z1 in the vertical direction Z. Although the type of article 2 is not limited thereto, in the present embodiment, the article 2 is a container (specifically, FOUP (Front Opening Unified Pod)) for housing a semiconductor wafer, and the holding unit 21 holds the article 2 by gripping a flange part formed on an upper part of the article 2. As shown in FIG. 6, the holding unit 21 is provided with a holding drive unit M3 (e.g., solenoid or electric motor) that switches the state of the holding unit 21, and, due to the drive of the holding drive unit M3, the state of the holding unit 21 is switched between a holding state of holding the article 2 and a holding release state in which holding of the article 2 is released.

As shown in FIG. 2, the transport vehicle 1 is provided with a lifting unit 22 that raises and lowers the holding unit 21 in the vertical direction Z relative to the travel unit 10. As shown in FIG. 6, the lifting unit 22 is provided with a lifting drive unit M2 (e.g., electric motor such as a servo motor) that raises and lowers the holding unit 21, and, due to the drive of the lifting drive unit M2, the holding unit 21 is raised and lowered. In the present embodiment, the lifting unit 22 is disposed on a lower side Z2 in the vertical direction Z relative to the travel unit 10. The lifting unit 22 is also disposed on the lower side Z2 relative to the travel rails 41. Specifically, the transport vehicle 1 is provided with a main body part 20 coupled to the travel unit 10 (here, a pair of travel units 10), and the main body part 20 is supported by the travel units 10 in a state of being disposed on the lower side Z2 relative to the travel units 10. Also, as shown in FIG. 2, the lifting unit 22 is provided in the main body part 20. In the present embodiment, the vertical direction Z corresponds to the “lifting direction.”

In the case where the travel units 10 perform a travel operation for traveling along the travel path 40, the holding unit 21 is raised/lowered to a first height H1. Also, while the travel units 10 are performing the travel operation, the height (position in the vertical direction Z) of the holding unit 21 is maintained at the first height H1. As shown in FIG. 2, in the present embodiment, the first height H1 is the height at which the article 2 held by the holding unit 21 is housed in the main body part 20. The article 2 held by the holding unit 21 that is positioned at the first height H1 is housed in the main body part 20, so as to be covered by the main body part 20 from both sides in the path longitudinal direction X. Also, in the case where the transport vehicle 1 performs a transfer operation for transferring the article 2 between the holding unit 21 and a transfer target location 4, the holding unit 21 is raised/lowered to a second height H2 corresponding to the transfer target location 4. The second height H2 is set according to the height of each transfer target location 4. The transfer target location 4 is, for example, a load port of a processing device that processes the article 2 or a storage shelf of a storage device that stores the article 2. FIG. 2 shows a supporting part that supports the article 2 from the lower side Z2 as an example of the transfer target location 4. In the present embodiment, the second height H2 is lower than the first height H1.

In the present embodiment, the lifting unit 22 raises/lowers the holding unit 21, in a state where the holding unit 21 is supported in a suspended manner. Specifically, the holding unit 21 is coupled to a leading end part of a transmission member 23 such as a belt or a wire. Also, the lifting unit 22 uses the drive of the lifting drive unit M2 to rotate a winding body around which the transmission member 23 is wound, and raises or lowers the holding unit 21 by winding up or letting out the transmission member 23. In this way, in the present embodiment, the lifting unit 22 raises and lowers the holding unit 21 in a suspended manner, and thus the article 2 is held by the holding unit 21 so as to be suspended from the lifting unit 22.

As shown in FIG. 6, the article transport facility 100 is provided with a control unit 30 that controls operations of the transport vehicle 1. The control unit 30 is provided with a computation processing device such as CPU together with peripheral circuits such as a memory and the like, and the functions of the control unit 30 are realized through cooperation between this hardware and programs that are executed on hardware such as the computation processing device. The control unit 30 may be provided in the transport vehicle 1, and may also be provided independently to the transport vehicle 1. Also, in the case where the control unit 30 is provided with separate pieces of hardware that can communicate with each other, some of the hardware may be provided in the transport vehicle 1, and the remaining hardware may be provided independently to the transport vehicle 1. The technical features of the control unit 30 disclosed in this specification are also applicable to a control method for controlling the transport vehicle 1 of the article transport facility 100, and a control method of the transport vehicle 1 is also disclosed in this specification.

The control unit 30 causes the travel units 10 to perform the travel operation for traveling along the travel path 40, by controlling the drive of the travel drive unit M1. In the case of transporting the article 2 that is being held by the holding unit 21 to the transfer target location 4, the control unit 30 causes the travel units 10 to perform the travel operation in a state where the holding unit 21 is holding the article 2. Also, the control unit 30 causes the lifting unit 22 to perform the lifting operation for raising and lowering the holding unit 21 by controlling the drive of the lifting drive unit M2, and causes the holding unit 21 to performs the holding state switching operation for switching the state of the holding unit 21 between the holding state and the holding release state by controlling the drive of the holding drive unit M3. In the case of transferring the article 2 between the transfer target location 4 and the holding unit 21, the control unit 30 causes the lifting unit 22 to perform the lifting operation, together with causing the holding unit 21 to perform the holding state switching operation. Also, the control unit 30 causes the travel units 10 to perform the guide position switching operation for switching the position of the guide wheels 12 between the right-side guide position and the left-side guide position, by controlling the drive of the switching drive unit M4. The control unit 30 moves the guide wheels 12 to a position that depends on the advancing direction into the merge part 40a, the leaving direction from the branch part 40b and the like, before the transport vehicle 1 advances along a portion of the travel path 40 where the guide rail 42 is provided.

Although not described in detail, the control unit 30 derives an estimated current position which is the estimated position of the transport vehicle 1 currently, and controls the travel operation of the travel units 10. For example, a configuration can be adopted in which the transport vehicle 1 is provided with a reading device that reads address information of an information holding body (information indicting the position where the information holding body is provided) provided in a plurality of positions along the travel path 40, and a measuring device that measures the travel distance of the travel units 10, and the control unit 30 derives the estimated current position of the transport vehicle 1, based on the address information read by the reading device and the travel distance of the travel units 10 measured by the measuring device (specifically, the travel distance after the reading device reads the address information). For example, a one-dimensional code or a two-dimensional code can be used as the information holding body, and a one-dimensional code reader or a two-dimensional code reader can be used as the reading device. Also, for example, a rotary encoder can be used as the measuring device.

The control unit 30 causes the transport vehicle 1 to travel to a position corresponding to the transfer target location 4 (here, position on upper side Z1 relative to transfer target location 4 and overlapping with transfer target location 4 in plan view), by causing the travel units 10 to perform the travel operation. After causing the lifting unit 22 to perform the lifting operation for raising/lowering (here, lowering) the holding unit 21 from the first height H1 to the second height H2, in a state where the transport vehicle 1 is stopped at the above position, the control unit 30 then causes the holding unit 21 to perform the holding state switching operation, and thereafter causes the lifting unit 22 to perform the lifting operation for raising/lowering (here, raising) the holding unit 21 from the second height H2 to the first height H1, thereby transferring the article 2 between the transfer target location 4 and the holding unit 21. In the case of transferring the article 2 from the holding unit 21 to the transfer target location 4, the article 2 being held by the holding unit 21 is unloaded at the transfer target location 4, by switching the state of the holding unit 21 from the holding state to the holding release state. Also, in the case of transferring the article 2 from the transfer target location 4 to the holding unit 21, the article 2 that is placed at the transfer target location 4 is removed from the transfer target location 4, by switching the state of the holding unit 21 from the holding release state to the holding state.

The control unit 30 causes the lifting unit 22 to perform the lifting operation for raising/lowering the holding unit 21, by executing feedback control for controlling the lifting unit 22 to move the position of the holding unit 21 in the vertical direction Z closer to a target position while changing the target position. Note that the target position is a height (position in the vertical direction Z), and the control unit 30 changes the target position from a start height through to an end height. Specifically, in the case of raising/lowering the holding unit 21 from the first height H1 to the second height H2, the control unit 30 changes the target position from the first height H1 which is the start height through to the second height H2 which is the end height, and, in the case of raising/lowering the holding unit 21 from the second height H2 to the first height H1, the control unit 30 changes the target position from the second height H2 which is the start height through to the first height H1 which is the end height. The control unit 30 generates a lifting speed pattern for raising/lowering the holding unit 21 from the start height through to the end height, and generates a target position for every set time period (every computation period) that depends on the generated lifting speed pattern, for example.

Also, the control unit 30 fixes the target position and executes feedback control, while the travel units 10 are being caused to perform the travel operation along the travel path 40 in a state where the holding unit 21 is holding the article 2. In the present embodiment, the control unit 30 fixes the target position to the first height H1 and executes feedback control, while the travel units 10 are being caused to perform the travel operation along the travel path 40 in a state where the holding unit 21 is holding the article 2. Since the height of the holding unit 21 during the travel operation is held by feedback control in this way, a configuration can also be adopted in which the lifting unit 22 is not provided with a brake (e.g., mechanical brake) for holding the height of the holding unit 21.

The lifting drive unit M2 is provided with a feedback control system such as illustrated in FIG. 7, and the control unit 30 executes feedback control, by outputting a position instruction that depends on the target position to the lifting drive unit M2. The lifting drive unit M2 is provided with a motor 50 (here, electric motor such as a servo motor) as a drive power source that generates drive power for raising and lowering the holding unit 21, and the lifting drive unit M2 drives the motor 50 by feedback control to track the position instruction that is input from the control unit 30. In the present embodiment, the motor 50 is configured to rotate the winding body around which the transmission member 23 is wound.

The feedback control that is executed by the control unit 30 includes at least position loop control. In the present embodiment, the lifting drive unit M2 is provided with the feedback control system shown in FIG. 7, and the feedback control that is executed by the control unit 30 includes position loop control and speed loop control. As shown in FIG. 7, in the present embodiment, the lifting drive unit M2 is provided with a first difference device 51, a second difference device 52, a position control unit 53, a speed control unit 54, a torque control unit 55, a detection unit 56, and a speed computation unit 57, in addition to the motor 50.

Position loop control is control for generating a speed instruction, based on a position loop gain and a deviation (position deviation) between a position instruction that depends on the target position and a feedback value corresponding to the position instruction. In the present embodiment, the feedback value corresponding to the position instruction is the rotation position of the motor 50. In the example shown in FIG. 7, the rotation position of the motor 50 is detected by the detection unit 56 (e.g., encoder). The first difference device 51 computes the position deviation by subtracting the rotation position of the motor 50 detected by the detection unit 56 from the position instruction that is input from the control unit 30. The position control unit 53 then generates the speed instruction, by executing at least proportional control out of proportional control, integral control and differential control, based on the computed position deviation and the position loop gain. In the example shown in FIG. 7, position loop control is executed in this way.

Since the position control unit 53 executes at least proportional control, the position loop gain includes at least a position proportional gain Kp. The position proportional gain Kp is the gain with which the position deviation is multiplied when generating the speed instruction. In the case where the position control unit 53 also executes integral control (e.g., executes proportional integral control), the position loop gain includes a position integral gain, and in the case where the position control unit 53 also executes differential control (e.g., executes proportional integral differential control), the position loop gain includes a position differential gain. The position integral gain is the gain with which the integral value of the position deviation is multiplied when generating the speed instruction, and the position differential gain is the gain with which the differential value of the position deviation is multiplied when generating the speed instruction. Note that, in this specification, the reciprocal of the integral time constant (time constant of integral control) is taken as the position integral gain, rather than a value obtained by multiplying the reciprocal of the integral time constant by the position proportional gain Kp.

Speed loop control is control for generating the drive instruction of the holding unit 21, based on a speed loop gain and a deviation (speed deviation) between a speed instruction and the feedback value corresponding to the speed instruction. In the present embodiment, the feedback value corresponding to the speed instruction is the rotation speed of the motor 50, and the drive instruction of the holding unit 21 is a torque instruction of the motor 50. In the example shown in FIG. 7, the rotation speed of the motor 50 is computed by the speed computation unit 57 differentiating the rotation position of the motor 50 detected by the detection unit 56. The second difference device 52 computes the speed deviation by subtracting the rotation speed of the motor 50 computed by the speed computation unit 57 from the speed instruction generated by the position control unit 53. The speed control unit 54 then generates the torque instruction, by executing at least proportional control out of proportional control, integral control and differential control, based on the computed speed deviation and the speed loop gain. In the example shown in FIG. 7, speed loop control is executed in this way.

Since the speed control unit 54 executes at least proportional control, the speed loop gain includes at least a speed proportional gain Kvp. The speed proportional gain Kvp is the gain with which the speed deviation is multiplied when generating the torque instruction. In the case where the speed control unit 54 also executes integral control (e.g., executes proportional integral control), the speed loop gain includes a speed integral gain Kvi, and, in the case where the speed control unit 54 also executes differential control (e.g., executes proportional integral differential control), the speed loop gain includes a speed differential gain. The speed integral gain Kvi is the gain with which the integral value of the speed deviation is multiplied when generating the torque instruction, and the speed differential gain is the gain with which the differential value of the speed deviation is multiplied when generating the torque instruction. Note that, in this specification, the reciprocal of the integral time constant (time constant of integral control) is taken as the speed integral gain Kvi, rather than a value obtained by multiplying the reciprocal of the integral time constant by the speed proportional gain Kvp.

The drive power source (here, motor 50) that generates drive power for raising and lowering the holding unit 21 is driven based on the drive instruction (here, torque instruction) of the holding unit 21 generated by speed loop control. In the example shown in FIG. 7, the torque control unit 55 generates a current instruction that depends on the torque instruction generated by the speed control unit 54, and the drive of the motor 50 is controlled to output torque that depends on the torque instruction, due to electrical current that depends on the current instruction being supplied to the motor 50.

Note that the feedback control system with which the lifting drive unit M2 is provided may be provided with a feedforward control unit. For example, a configuration can be adopted in which a speed feedforward value generated by the feedforward control unit is added to the speed instruction generated by the position control unit 53, or in which a torque feedforward value generated by the feedforward control unit is added to the torque instruction generated by the speed control unit 54.

Incidentally, the gain of the feedback control during the lifting operation of the holding unit 21 by the lifting unit 22 is generally required to be set comparatively high, in order to appropriately ensure control accuracy of the position (position in vertical direction Z; same applies below) of the holding unit 21. On the other hand, if the gain of the feedback control during the travel operation of the travel units 10 is high, there is a risk that, in the case where the holding unit 21 is displaced in the vertical direction Z from the target position by vibration of the travel units 10 or the like, large vibrations (strong vibrations) will be transmitted to the article 2 held by the holding unit 21, due to the corrective force for returning the position of the holding unit 21 to the target position being excessive. In view of this point, the control unit 30 is constituted to reduce the travel operation gain, which is the gain of feedback control during the travel operation, to lower than the lifting operation gain, which is the gain of feedback control during the lifting operation. The control unit 30 reduces the travel operation gain to lower than the lifting operation gain, at least during the travel operation in which the travel units 10 travel along the travel path 40 in a state where the article 2 is held by the holding unit 21. Thus, the amount of corrective force can be kept at a moderate level, in the case where the holding unit 21 is displaced in the vertical direction Z from the target position during the travel operation, and, as a result, the position of the holding unit 21 can be converged to the target position, while absorbing the displacement of the holding unit 21 in the vertical direction Z, such that large vibrations are not transmitted to the article 2 held by the holding unit 21.

Here, reducing the gain of feedback control means reducing at least one of the gains of feedback control. In the present embodiment, the gains of feedback control include the position loop gain and the speed loop gain, the position loop gain includes the position proportional gain Kp, and the speed loop gain includes the speed proportional gain Kvp. In the present embodiment, the speed control unit 54 generates the torque instruction, by executing at least proportional control and integral control out of proportional control, integral control and differential control. Thus, the speed loop gain also includes the speed integral gain Kvi. That is, in the present embodiment, the speed loop gain includes the speed proportional gain Kvp and the speed integral gain Kvi. Therefore, in the present embodiment, the gains of feedback control includes the position proportional gain Kp, the speed proportional gain Kvp and the speed integral gain Kvi, and the control unit 30 reduces the gain of feedback control (specifically, reduces the travel operation gain to lower than the lifting operation gain), by reducing at least one of the position proportional gain Kp, the speed proportional gain Kvp, and the speed integral gain Kvi.

In the present embodiment, in the case of changing the gain of feedback control (at least one of the gains) between the travel operation gain and the lifting operation gain, the control unit 30 changes the gain of feedback control in stages, so as to pass through the states of gains between the travel operation gain and the lifting operation gain. Specifically, the control unit 30 changes the gain of feedback control in stages, so as to pass through the states of gains between the travel operation gain and the lifting operation gain, by changing at least one of the gains of feedback control over a plurality of stages. Here, change performed over a plurality of stages means changing from a start value, which is the value at the start of the change, to one or more intermediate values (values between the start value and end value), and then to an end value, which is the value at the end of the change, rather than changing from the start value to the end value in one stage. In the case where a plurality of intermediate values are set, changing successively from the start value to the plurality of intermediate values, and then to the end value is performed so as to gradually approach the end value from the start value. For example, in the case of change performed over two stages, changing from the start value to one intermediate value and then to the end value is performed, and in the case of change performed over three stages, changing successively from the start value to a first intermediate value and a second intermediate value (value between first intermediate value and end value), and then to the end value is performed. The state where the gain that is changed over a plurality of stages is an intermediate value is the state of gains between the travel operation gain and the lifting operation gain.

In the present embodiment, the gains of feedback control include the position proportional gain Kp, the speed proportional gain Kvp, and the speed integral gain Kvi. Also, in the present embodiment, the travel operation gain is reduced to lower than the lifting operation gain, by reducing the value during the travel operation to lower than the value during the lifting operation, with regard to each of the position proportional gain Kp, the speed proportional gain Kvp, and the speed integral gain Kvi. That is, during the travel operation, the pattern (Kp, Kvp, Kvi) of the combination of the position proportional gain Kp, the speed proportional gain Kvp and the speed integral gain Kvi will be a pattern (Kp_R, Kvp_R, Kvi_R) during the travel operation, which is a pattern suitable for during the travel operation, and during the lifting operation, the pattern (Kp, Kvp, Kvi) of the combination of these three gains will be a pattern (Kp_E, KvpE, Kvi_E) during the lifting operation, which is a pattern suitable for during the lifting operation. Here, Kp_R<Kp_E, Kvp_R<Kvp_E, and Kvi_R<Kvi_E.

In the case of changing each of the position proportional gain Kp, the speed proportional gain Kvp and the speed integral gain Kvi between a value suitable for during the travel operation and a value suitable for during the lifting operation as described above, the article 2 held by the holding unit 21 is easy inhibited from being greatly displaced (from vibrating greatly) in the vertical direction Z when the speed proportional gain Kvp is changed over a plurality of stages between Kvp_R and Kvp_E, according to the knowledge gained by the inventor of the present invention. Thus, for example, it is favorable for the control unit 30 to be configured to change the gain of feedback control in stages, by changing at least the speed proportional gain Kvp over a plurality of stages.

In the example shown in FIG. 8, it is assumed that the control unit 30 changes the gain of feedback control in stages between the travel operation gain and the lifting operation gain, by changing the speed proportional gain Kvp over three stages. FIG. 8 shows an example of the temporal change in the pattern (Kp, Kvp, Kvi) of the combination of the position proportional gain Kp, the speed proportional gain Kvp and the speed integral gain Kvi, with pattern 1 being the above-mentioned lifting operation pattern (Kp_E, Kvp_E, Kvi_E), and pattern 4 being the above-mentioned travel operation pattern (Kp_R, Kvp_R, Kvi_R). Also, pattern 2 is a pattern in which the speed proportional gain Kvp is Kvp_H between Kvp_R and Kvp_E, and pattern 3 is a pattern in which the speed proportional gain Kvp is Kvp_L between Kvp_R and Kvp_H. In the case where the control unit 30 changes the position proportional gain Kp and the speed integral gain Kvi in one stage, pattern 2 will be (Kp_R, Kvp_H, Kvi_R), and pattern 3 will be (Kp_R, Kvp_L, Kvi_R), for example. In the example shown in FIG. 8, the state where the pattern of the gain of feedback control is pattern 2 and the state where the pattern of the gain of feedback control is pattern 3 are the states of gains between the travel operation gain and the lifting operation gain.

In the example shown in FIG. 8, in the case of ending the lifting operation and starting the travel operation, the control unit 30 changes the pattern of the gain of feedback control successively from pattern 1 to pattern 2 and pattern 3, and then to pattern 4. The gain of feedback control is thereby changed from the lifting operation gain to the travel operation gain, by the gain of feedback control being changed in stages. Also, in the case of ending the travel operation and starting the lifting operation, the control unit 30 changes the pattern of the gain of feedback control successively from pattern 4 to pattern 3 and pattern 2, and then to pattern 1. The gain of feedback control is thereby changed from the travel operation gain to the lifting operation gain, by the gain of feedback control being changed in stages. In the example shown in FIG. 8, the pattern of the gain of feedback control is changed, such that change of the gain of feedback control from the lifting operation gain to the travel operation gain is started to coincide with the start of the travel operation, and change of the gain of feedback control from the travel operation gain to the lifting operation gain ends to coincide with the end of the travel operation. The control unit 30 changes the gain of feedback control to coincide with the change of pattern, with reference to a gain table in which the values of gains are prescribed for every pattern, for example.

Incidentally, in the present embodiment, in parts of the travel path 40 (specifically, merge part 40a, branch part 40b, etc.), the travel state of the travel units 10 changes between a state of traveling with both wheels 11 on the left and right sides in contact with the travel rails 41 and a state of traveling with only one of the wheels 11 on the left and right sides in contact with the travel rails 41 and the guide wheels 12 in contact with the guide rail 42. Thus, in portions of the travel path 40 where the merge part 40a, the branch part 40b and the like are provided, vibration of the travel units 10 accompanying travel tends to increase compared with other portions of the travel path 40. That is, as shown in FIG. 3, in the present embodiment, the travel path 40 includes first sections A1 and second sections A2 in which vibration of the travel units 10 accompanying travel is large compared with the first sections A1. For example, a section (zone) in which the merge part 40a or the branch part 40b is provided or a section in which the guide rail 42 is provided can be defined as a second section A2, and sections other than the second sections A2 can be defined as first sections A1. Note that, in the case where a discontinuous region or level difference of a size greater than or equal to a prescribed value is formed in a joint of the travel rails 41, the section including the joint may be defined as a second section A2.

In the case where the travel path 40 includes first sections A1 and second sections A2 in this way, the control unit 30 may be configured to reduce the travel operation gain for when the travel units 10 are traveling through a second section A2 to lower than the travel operation gain for when the travel units 10 are traveling through a first section A1. In the case where four patterns of the gain of feedback control are set as shown in the example shown in FIG. 8, for example, a configuration can be adopted in which the control unit 30 sets the gain of feedback control based on pattern 3, while the travel units 10 are traveling through a first section A1, and sets the gain of feedback control based on pattern 4, while the travel units 10 are traveling through a second section A2. Note that the control unit 30 determines whether the travel units 10 are traveling through a first section A1 or a second section A2, based on the estimated current position of the transport vehicle 1, for example.

### OTHER EMBODIMENTS

Next, other embodiments of the article transport facility will be described.

(1) In the above embodiment, an example is described in which, in the case of changing the gain of feedback control between the travel operation gain and the lifting operation gain, the control unit 30 changes the gain of feedback control in stages, so as to pass through the states of gains between the travel operation gain and the lifting operation gain. However, the present disclosure is not limited to such a configuration, and a configuration can also be adopted in which, in the case of changing the gain of feedback control between the travel operation gain and the lifting operation gain, the control unit 30 continuously changes (i.e., gradually decreases or gradually increases) the gain of feedback control so as to pass through the states of gain between the travel operation gain and the lifting operation gain. In this case, the states of gains between the travel operation gain and the lifting operation gain are states where the gain of feedback control changes continuously rather than uniformly.

(2) In the above embodiment, an example is described in which, in the case of changing the gain of feedback control between the travel operation gain and the lifting operation gain, the control unit 30 changes the gain of feedback control so as to pass through the states of gains between the travel operation gain and the lifting operation gain. However, the present disclosure is not limited to such a configuration, and a configuration can also be adopted in which the control unit 30 changes the gain of feedback control stepwise between the travel operation gain and the lifting operation gain.

(3) In the above embodiment, an example is described in which the lifting unit 22 is disposed on the lower side Z2 relative to the travel units 10. However, the present disclosure is not limited to such a configuration, and a configuration can also be adopted in which the lifting unit 22 is disposed on the upper side Z1 relative to the travel units 10 (in other words, a configuration in which the main body part 20 is disposed on the upper side Z1 relative to the travel units 10), for example. Also, in the embodiment, an example is described in which the holding unit 21 holds the article 2 from the upper side Z1. However, the present disclosure is not limited to such a configuration, and a configuration can also be adopted in which the holding unit 21 holds the article 2 from the lower side Z2 (e.g., a configuration in which the holding unit 21 holds the article 2 by supporting the undersurface of the article 2), for example.

(4) Note that the configuration disclosed in each of the above-mentioned embodiments can also be applied in combination with configurations disclosed in other embodiments (including combinations of embodiments described as other embodiments), as long as no conflicts arise. The embodiments disclosed in this specification are merely illustrative in all respects, with regard also to the other configurations. Accordingly, various modifications can be made as appropriate, without departing from the spirit of the disclosure.

### SUMMARY OF THE EMBODIMENTS

Hereinafter, a summary of the article transport facility described above will be described.

The article transport facility includes a transport vehicle configured to travel along a travel path and transport an article, and a control unit configured to control operations of the transport vehicle, the transport vehicle including a travel unit configured to travel along the travel path, a holding unit configured to hold the article, and a lifting unit configured to raise/lower the holding unit in a lifting direction relative to the travel unit, the control unit causing the lifting unit to perform a lifting operation for raising/lowering the holding unit, by executing feedback control for controlling the lifting unit to move a position of the holding unit in the lifting direction closer to a target position while changing the target position, and executing the feedback control with the target position fixed while causing the travel unit to perform a travel operation for traveling along the travel path in a state where the holding unit is holding the article, and the control unit reducing a travel operation gain which is a gain of the feedback control during the travel operation to lower than a lifting operation gain which is a gain of the feedback control during the lifting operation.

In order to shorten the positioning time of the holding unit and the like, it is generally sought to set the gain of feedback control during the lifting operation of the holding unit by the lifting unit (lifting operation gain) comparatively high. According to this configuration, the gain of feedback control during the travel operation of the travel unit (travel operation gain) can be set low, while setting a high lifting operation gain. By setting a low travel operation gain in this way, in the case where the holding unit is displaced from the target position during the travel operation, the amount of corrective force for returning the position of the holding unit in the lifting direction to the target position can be kept at a moderate level, and vibration that is transmitted to the article held by the holding unit can be kept small. In this way, according to this configuration, vibration in the vertical direction that is transmitted to the article during the travel operation of the travel unit can be reduced, with a comparatively simple control configuration that reduces the travel operation gain to lower than the lifting operation gain.

Here, it is favorable for the control unit, in a case of changing the gain of the feedback control between the travel operation gain and the lifting operation gain, to change the gain of feedback control in stages or continuously, so as to pass through a state of a gain between the travel operation gain and the lifting operation gain.

According to this configuration, the gain of feedback control can be changed, while suppressing abrupt change in the responsiveness of feedback control, compared with the case where the gain of feedback control is changed stepwise between the travel operation gain and the lifting operation gain. Therefore, the gain of feedback control can be changed, while suppressing vibration of articles caused by the drive instruction of the holding unit that is generated by feedback control changing abruptly.

In a configuration in which the control unit changes the gain of feedback control in stages or continuously, it is favorable for the feedback control to include position loop control and speed loop control, the position loop control being control for generating a speed instruction, based on a position loop gain and a deviation between a position instruction that depends on the target position and a feedback value corresponding to the position instruction, and the speed loop control being control for generating a drive instruction of the holding unit, based on a speed loop gain and a deviation between the speed instruction and a feedback value corresponding to the speed instruction, and for the position loop gain to include at least a position proportional gain, the speed loop gain to include at least a speed proportional gain and a speed integral gain, and the control unit to change the gain of feedback control in stages, by changing at least the speed proportional gain over a plurality of stages.

As described above, in the case where the gains of feedback control include position proportional gain, speed proportional gain and speed integral gain, speed proportional gain tends to exert the greatest influence on the responsiveness of feedback control out these gains According to this configuration, in the case of changing the gain of feedback control in stages, at least the speed proportional gain is changed over a plurality of stages, and thus abrupt change in the drive instruction of the holding unit generated by feedback control tends to be suppressed, even in the case where the gain of feedback control is changed in stages rather than continuously.

In the article transport facility having the above configurations, the travel path may include a first section and a second section in which vibration of the travel unit accompanying travel is large compared with the first section, and it is favorable for the control unit to reduce the travel operation gain for when the travel unit is traveling through the second section to lower than the travel operation gain for when the travel unit is traveling through the first section.

According to this configuration, vibration in the vertical direction tends not to transmitted to the article due to reducing the travel operation gain, while the travel unit is traveling through a second section in which the travel unit tends to vibrate, and the position of the holding unit can be accurately aligned with the target position by setting the travel operation gain on the high side, while the travel unit is traveling through a first section in which the travel unit tends not to vibrate compared with the second section.

The article transport facility according to the present disclosure need only achieve at least one of the effects described above.

What is claimed is:

1. An article transport facility comprising:
a transport vehicle configured to travel along a travel path and transport an article; and
a control unit configured to control operations of the transport vehicle,
wherein the transport vehicle includes:
a travel unit configured to travel along the travel path;
a holding unit configured to hold the article; and
a lifting unit configured to raise/lower the holding unit in a lifting direction relative to the travel unit,
wherein the control unit causes the lifting unit to perform a lifting operation for raising/lowering the holding unit by executing feedback control for controlling the lifting unit to move a position of the holding unit in the lifting direction closer to a target position while changing the target position, and the control unit executes the feedback control with the target position fixed while causing the travel unit to perform a travel operation for traveling along the travel path in a state where the holding unit is holding the article, and
wherein the control unit reduces a travel operation gain which is a gain of the feedback control during the travel operation to lower than a lifting operation gain which is a gain of the feedback control during the lifting operation.

2. The article transport facility according to claim 1,
wherein the control unit, in a case of changing the gain of the feedback control between the travel operation gain and the lifting operation gain, changes the gain of feedback control in stages or continuously, so as to pass through a state of a gain between the travel operation gain and the lifting operation gain.

3. The article transport facility according to claim 2, wherein:
the feedback control includes position loop control and speed loop control,
the position loop control is control for generating a speed instruction based on a position loop gain and a deviation between a position instruction that depends on the target position and a feedback value corresponding to the position instruction,
the speed loop control is control for generating a drive instruction of the holding unit based on a speed loop gain and a deviation between the speed instruction and a feedback value corresponding to the speed instruction,
the position loop gain includes at least a position proportional gain,
the speed loop gain includes at least a speed proportional gain and a speed integral gain, and
the control unit changes the gain of feedback control in stages by changing at least the speed proportional gain over a plurality of stages.

4. The article transport facility according to claim 1,
wherein the travel path includes a first section and a second section in which vibration of the travel unit accompanying travel is large compared with the first section, and
wherein the control unit reduces the travel operation gain for when the travel unit is traveling through the second section to lower than the travel operation gain for when the travel unit is traveling through the first section.
